(19) United States
(12) Patent Application Publication
(10) Pub. No.: US 2015/0223348 A1
(43) Pub. Date: Aug. 6, 2015

(54) METHOD AND SYSTEM FOR PROVIDING A SELF-CONTAINED WIRELESS NETWORK ENVIRONMENT THAT MANAGES AND STORES MULTIPLE TABLET DEVICES

(71) Applicant: Quantilus Inc., New York, NY (US)

(72) Inventors: Sanjay Sagar, Jersey City, NY (US); Debarshi Chaudhury, New York, NY (US)

(73) Assignee: Quantilus Inc., New York, NY (US)

(21) Appl. No.: 14/172,927

(22) Filed: Feb. 5, 2014

(51) Int. Cl. H05K 5/00; G06F 1/26; G06F 1/28; H04W 84/02

(52) U.S. Cl. CPC H05K 5/00; H04W 84/02; G06F 1/26; G06F 1/28

(57) ABSTRACT

A computer-implemented method and system for providing a self-contained wireless network environment that serves content and application, manages, and controls multiple tablet devices. The computer-implemented method includes registering multiple electronic devices with a server application placed within a server embedded in a cart. The electronic devices are tablet devices. Further, the computer-implemented method includes managing the registered electronic devices.

### TECHNICAL FIELD

Embodiments of the disclosure relate generally, to simultaneous charging of a multitude of tablet devices and more specifically, to provide a self-contained wireless network environment and content and application server that manages and stores multiple tablet devices.

### BACKGROUND

A large number of educational institutes around the world are adopting tablets to replace books and notebooks in a classroom. In this new paradigm, each student is provided with a tablet. With a considerable number of students in a given educational institute, managing and storing the tablets for all students can become a tedious job. The tablets could be in use all day therefore need to be charged after-hours. Classrooms are unlikely to have ample infrastructure (power outlets) to charge a large number of tablets concurrently. Consequently, charging the tablets remains a challenge.

Further, several educational institutes, such as schools, may not have locations in a classroom to securely store the tablets. Occasionally, the tablets needs to be transported from one location to another within the school premises. As a result, transportation of all tablets becomes a wearying task.

The applications and content that drives the programs in the tablets need to reside on servers, which can be accessed by the tablets using wireless networks. As a significant population of schools may not have enough network bandwidth to permit all student tablets to connect to the internet simultaneously; a viable alternative is to bring the content and application servers into the classroom, making the need to connect to the Internet all the time redundant. An integrated server and wireless switch/router inside a classroom can provide a self-contained environment needed to enable communication between the servers and the tablets.

In light of the foregoing discussion, there is a need for an efficient method and system for providing a self-contained wireless network environment that servers content and application, manages, and stores multiple tablet devices in an institutional environment.

### SUMMARY

The above-mentioned needs are met by a computer-implemented method, a computer program product and a mechanical closet for providing a self-contained wireless network environment that serves content and application, manages, and stores multiple tablet devices.

An example of a computer-implemented method for providing a self-contained wireless network environment that serves content and application, and manages and controls multiple tablet devices. The computer-implemented method includes registering multiple electronic devices with a server application placed within a server embedded in the cart. The electronic devices are tablet devices. The computer-implemented method also includes managing versions of the applications, content units and operating system of the registered electronic devices.

An example of a computer program product stored on a non-transitory computer-readable medium that when executed by a processor, performs a method for providing a self-contained wireless network environment that serves content and application, manages, and controls multiple tablet devices. The computer program product includes registering multiple electronic devices with a server application placed within a server embedded in a cart. The electronic devices are tablet devices. Further, the computer program product also includes managing versions of an application, content units and operating system of the registered electronic devices.

An example of a system for providing a self-contained wireless network environment that serves content and application, manages, and controls multiple tablet devices. The system includes a plurality of slots arranged in multiple rows and columns. Each of the slots is adapted to hold a tablet device. The system also includes an Alternating Current power supply for charging multiple tablet devices simultaneously. Further, the system includes a Wi-Fi Router for providing Local Area Network for content delivery in a class-room and to provide internet connectivity (if and where available) to multiple tablet devices.

The features and advantages described in this summary and in the following detailed description are not all-inclusive, and particularly, many additional features and advantages will be apparent to one of ordinary skill in the relevant art in view of the drawings, specification, and claims hereof. Moreover, it should be noted that the language used in the specification has been principally selected for readability and instructional purposes, and may not have been selected to delineate or circumscribe the inventive subject matter, resort to the claims being necessary to determine such inventive subject matter.

### BRIEF DESCRIPTION OF THE FIGURES

In the following drawings like reference numbers are used to refer to like elements. Although the following figures depict various examples of the invention, the invention is not limited to the examples depicted in the figures.

FIG. 1 is a flow diagram illustrating a method providing a self-contained wireless network environment that serves content and application, manages, and controls multiple tablet devices, in accordance with one embodiment;

FIG. 2 is a block diagram illustrating a system for providing a self-contained wireless network environment that serves content and application, manages, and controls multiple tablet devices, in accordance with one embodiment;

FIG. 3 is a block diagram illustrating an exemplary server device, in accordance with one embodiment;

FIG. 4 is a perspective view of an mechanical closet to provide a self-contained wireless network environment that serves content and application, manages, and controls multiple tablet devices, in accordance with one embodiment; and

FIG. 5 is a partial cross-sectional view of the mechanical closet to a self-contained wireless network environment that serves content and application, manages, and controls multiple tablet devices, in accordance with one embodiment.

### DETAILED DESCRIPTION OF THE EMBODIMENTS

The above-mentioned needs are met by a method, computer program product and system for providing a self-contained wireless network environment that serves content and application, manages, and controls multiple tablet devices. The following detailed description is intended to provide example implementations to one of ordinary skill in the art, and is not intended to limit the invention to the explicit disclosure, as one or ordinary skill in the art will understand that variations can be substituted that are within the scope of the invention as described.

Plenty of Educational Institutions have taken over tablet-assisted teaching. This facilitates all students with individual tablets.

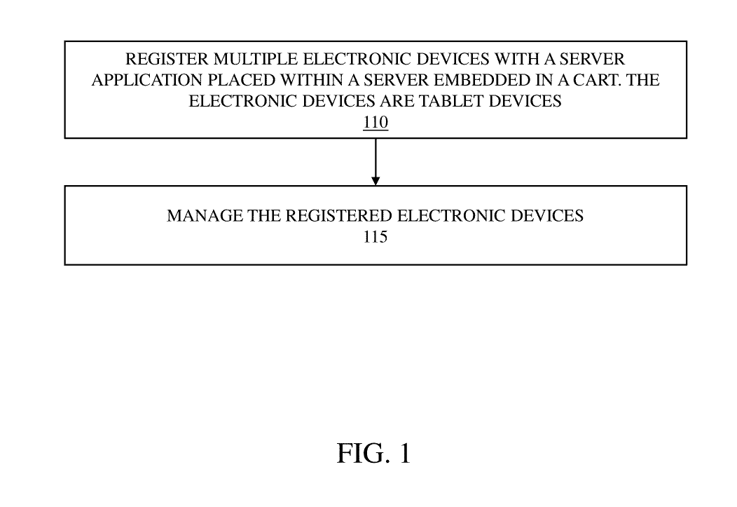

FIG. 1 is a flow diagram illustrating a method for providing a self-contained wireless network environment that serves content and application, manages, and controls multiple tablet devices, in accordance with one embodiment.

At step 110, multiple electronic devices are registered with a server placed within a cart. The electronic devices are tablets.

The cart is a mechanical closet with numerous slots. Typically, the cart is a wheeled vehicle normally moved by hand. In some embodiments, the number of slots can designed to be thirty or sixty. A tablet (tablet computer) is a type of a compact portable that has an Liquid Crystal Display (LCD) or a Light-Emitting Diode (LED) screen that enables the user to write using fingers (body part) or a special-purpose pen. Examples of tablet include, but are not limited to, Apple's Ipad, Samsung's Galaxy Tab, Microsoft's Surface, Hewlett-Packard's (HP) Touch Pad, Slate 2 and other manufacture's tablet. Further, most of the tablets use a protective cover. The cart can store the tablets along with their covers. In some embodiments, the cart can be applicable to store any other handheld devices, such as Personal Digital Assistants, mobile devices, Portable electronic keyboards and digital cameras.

Furthermore, the cart includes a server that is used to register the tablets stored in the cart and provide necessary support for creating a local area network, a web and a content server.

At step 115, the registered electronic devices are managed.

A managing application is installed on each tablet and communicates to a server application loaded on the embedded server to manage all the tablets stored in the cart. Applications version running on the tablets, content units and the operating system of the tablets can be managed. Examples of applications include, but is not limited to, education software, lesson and course delivery system, an assessment system and Presentation Graphic Software. An operating system (OS) is a collection of software that manages the resources of a computer. Examples of the OS include, but is not limited to, Android, iOS, Linux and Microsoft Windows.

Further, state of health (SOH) of the battery are tracked. Typically, the battery's SOH will be hundred percent at the time of manufacture and will later decrease over time and usage. The state of the battery signifies the percentage of total battery capacity available at a particular moment.

Furthermore, all the tablets are monitored continuously and reports are subsequently generated. The reports describe activities performed on the tablets. An administrator can access the reports duly.

The cart also includes a single Alternating Current (AC) power supply to all the stored electronic devices. As a result, multiple power supplies which are additional resources are eradicated. The single AC power supply pulls the required amount of electricity and converts the AC current to DC current. Whilst the tablets are stored in the cart overnight, the tablets are charged simultaneously.

Additionally, the cart provides adequate ventilation to the stored tablets. As a result, the tablets are maintained within an optimal temperature.

The proposed method manages the tablets left overnight in the cart by updating applications and contents contained within. The tablets are charged overnight.

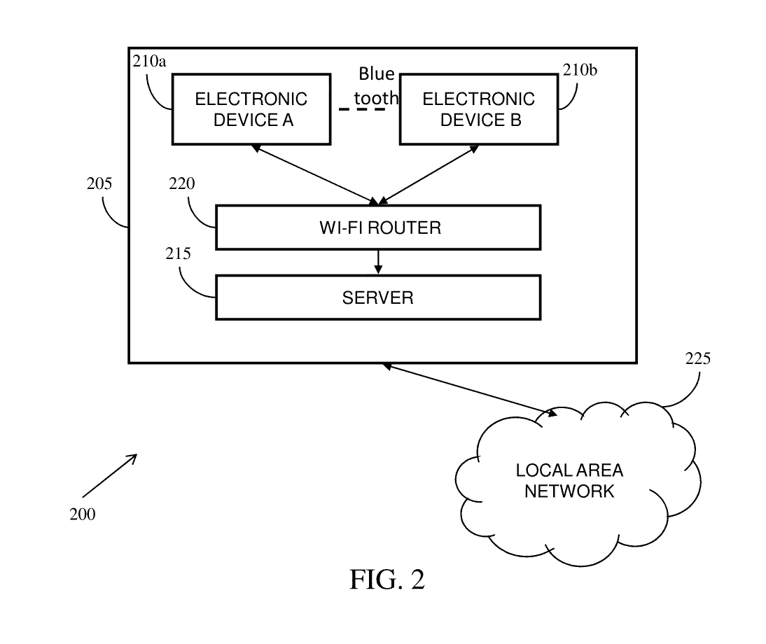

FIG. 2 is a block diagram illustrating a system for providing a self-contained wireless network environment that serves content and application, manages, and controls multiple tablet devices, in accordance with one embodiment.

The system 200 can implement the method described above. The system 200 includes a mechanical closet 205. The mechanical closet 205 is herein referred to as a cart and can store a plurality of electronic devices, for example, an electronic device A 210a and an electronic device B 210b. Essentially, the electronic devices are placed in slots arranged in multiple rows and columns. Further, the electronic devices are connected to a server 215 through a Wi-Fi Router 220. A switch is also connected to the server 215. In some embodiments, the Wi-Fi Router and the switch is installed in a single card that is subsequently connected to the server 215. The Wi-Fi Router 220 is used to provide Local Area Network for content delivery in a class-room and also provides internet connectivity to the multiple tablet devices. Basically, the system 200 provides serial connectivity between the server 215 and the electronic devices. The connectivity can be achieved by using a USB 2 interface. In some embodiments, any other connectivity interface (such as Wi-Fi) can also be used.

Further, the cart 205 includes a WiFi router 220 for creating a wireless Local Area Network (LAN) 220. The LAN is a computer network that interconnects to a group of computers in close proximity to each other such as in an office building, a school and a home. LAN supplies network connectivity to the tablets stored in the cart 205. Further, teachers and students are facilitated to share resources such as files, printers and other applications through the LAN. The LAN typically is a wireless LAN and in turn may connect to the Internet.

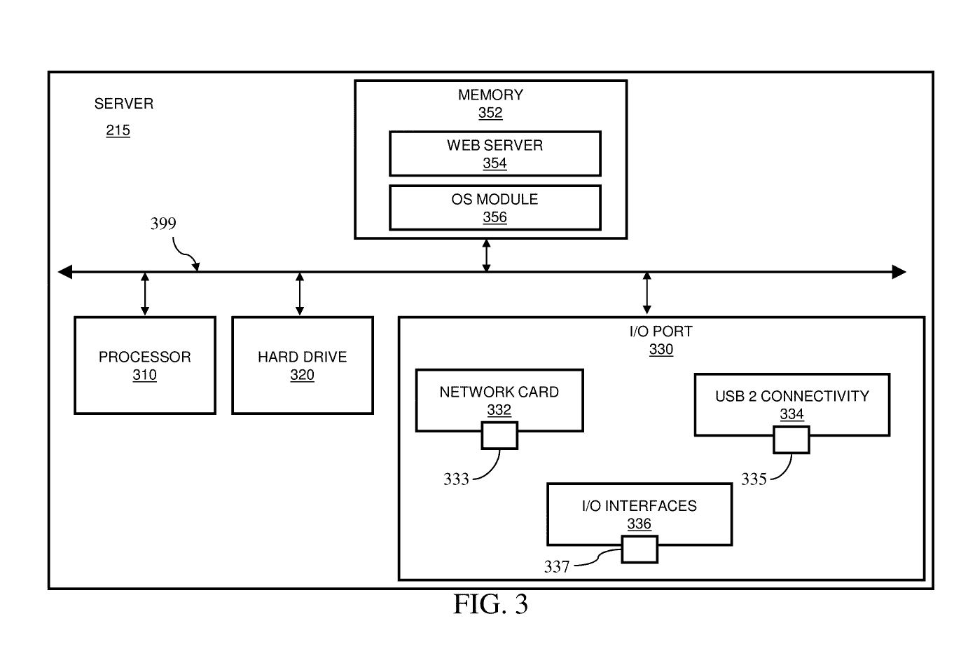

FIG. 3 is a block diagram illustrating an exemplary server device, for example the server 215 in accordance with one embodiment. Typically, the server 215 is embedded within the cart. The server 215 includes a processor 310, a hard drive 320, an I/O port 330, and a memory 352, coupled by a bus 399. In some embodiments, a plurality of I/O ports may be present.

Examples of the processor 310 includes, but is not limited to, a general purpose processor, an application-specific integrated circuit (ASIC), an FPGA (Field Programmable Gate Array), a RISC (Reduced Instruction Set Controller) processor, or an integrated circuit. The processor 310 can be a single core or a multiple core processor. In one embodiment, the processor 310 is specially suited for processing demands of location-aware reminders (for example, custom micro-code, and instruction fetching, pipelining or cache sizes). The processor 310 can be disposed on silicon or any other suitable material. In operation, the processor 310 can receive and execute instructions and data stored in the memory 352 or the hard drive 320. The hard drive 320 can be a platter-based storage device, a flash drive, an external drive, a persistent memory device, or other types of memory.

The hard drive 320 provides persistent (long term) storage for instructions and data. The I/O port 330 is an input/output panel including a network card 332 with an interface 333 along with USB 2 connectivity 334 with an interface 335 and I/O interfaces 336. The network card 332 can be, for example, a wired networking card (for example, a USB card, or an IEEE 802.3 card), a wireless networking card (for example, an IEEE 802.11 card, or a Bluetooth card), and a cellular networking card (for example, a 3G card). The interface 333 is configured according to networking compatibility. For example, a wired networking card includes a physical port to plug in a cord, and a wireless networking card includes an antennae. The network card 332 provides access to a communication channel on a network. The USB 2 Connectivity 334 allows serial connectivity between the server 215 and the tablet devices. The I/O interfaces 336 are web interfaces and are coupled to a physical port 337.

The memory 352 can be a RAM (Random Access Memory), a flash memory, a non-persistent memory device, or other devices capable of storing program instructions being executed. The memory 352 comprises an Operating System (OS) module 356 along with a web server 354. The OS module 356 can be one of Microsoft Windows® family of operating systems (for example, Windows 95, 98, Me, Windows NT, Windows 2000, Windows XP, Windows XP x64 Edition, Windows Vista, Windows CE, Windows Mobile), Linux, HP-UX, UNIX, Sun OS, Solaris, Mac OS X, Alpha OS, AIX, IRIX32, or IRIX64.

The web server 354 helps to deliver web content that can be accessed through the Wi-Fi network. The primary function of the web server is to deliver web pages to users. Said pages contain content and associated business logic.

As described herein, computer software products can be written in any of various suitable programming languages, such as C, C++, C#, Pascal, Fortran, Perl, JavaScript, AJAX, and Java. The computer software product can be an independent application with data input and data display modules. Alternatively, the computer software products can be classes that can be instantiated as distributed objects. The computer software products can also be component software, for example Java Beans (from Sun Microsystems) or Enterprise Java Beans (EJB from Sun Microsystems). Much functionality described herein can be implemented in computer software, computer hardware, or a combination.

Furthermore, a computer that is running the previously mentioned computer software can be connected to a network and can interface to other computers using the network. The network can be an intranet, internet, or the Internet, among others. The network can be a wired network (for example, using copper), telephone network, packet network, an optical network (for example, using optical fiber), or a wireless network, or a combination of such networks. For example, data and other information can be passed between the computer and components (or steps) of a system using a wireless network based on a protocol, for example Wi-Fi (IEEE standards 802.11, 802.11a, 802.11b, 802.11e, 802.11g, 802.11i, and 1802.11n). In one example, signals from the computer can be transferred, at least in part, wirelessly to components or other computers.

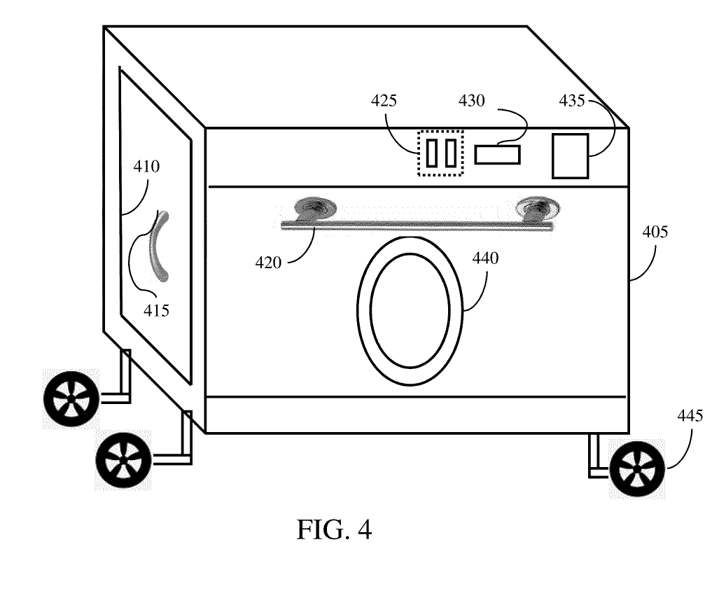

FIG. 4 is a perspective view of an mechanical closet to provide a self-contained wireless network environment and to store multiple tablet devices, in accordance with one embodiment.

The mechanical closet 405 is a robust, multifunction, self-contained, physical system designed to store a large number of tablets in organizations. The mechanical closet 405 provides a self-contained wireless network environment for the tablets. Further, body of the mechanical closet 405 is manufactured using metal bending technologies including sheet and pipe bending. The cart can be configured to store as many tablets as desired and acts as a charging station for the tablets stored within. For example, a thirty tablet configuration will have thirty slots in the cart. Similarly, a sixty tablet configuration will have sixty slots. All configurations mutually share similar functionalities with a difference in the number of slots in the cart. The slots provided in the cart can include any suitable shape and size that is useful for holding the tablets.

Further, the cart is fully covered by a door 410 that covers the stored tablets. In some embodiments, the door 410 includes a handle 415 and a lock (not shown in the figure) to ensure safety. In some embodiments, the lock can be inbuilt combination of locks or a standard pad lock. The handle 415 allows a user to open the door with ease. The cart also has ventilation such that sufficient air circulation is permitted around each stored tablet (so as to not allow tablet overheating).

The cart also includes a handle grip 420 to hold and drag the cart. Alongside the handle grip 420 are two USB ports 425, one RJ45 Network Interface 430 and a WiFi Antennae 435. The two Universal Serial Bus (USB) ports 425 is an external bus standard that can be used to connect up to various peripheral devices, such as mice, modems and keyboards. The RJ45 Network Interface 430 is a type of connector used for Ethernet networking. The RJ in RJ45 stands for “Registered Jack” and 45 refers to the number of the interface standard. Each RJ45 connector has eight pins, consequently, RJ45 cable contains eight separate wires. Further, the WiFi (also spelled as Wifi or Wi-Fi) Antenna 435 achieves the WiFi network that allows the tablets to connect to the Internet wirelessly using radio waves.

Additionally, the cart includes a recoiled power chord 440 and four rubber wheels 445 with brakes. The power chord 440 includes a power cable (from the wall) that retracts into a spiral. The spiral assembly eliminates danger from a dangling wire. In some embodiments, the cart can include more than four rubber wheels. The rubber wheels 445 aids a person to drag the cart from one location to another even on a hard-floored surface. Further, a paddle is located next to each of the rubber wheel. When the paddle is pressed, the rubber wheel is subsequently locked. As a result, the cart cannot be moved. Similarly, when the paddle is released, the rubber wheel is unlocked and the cart can be dragged.

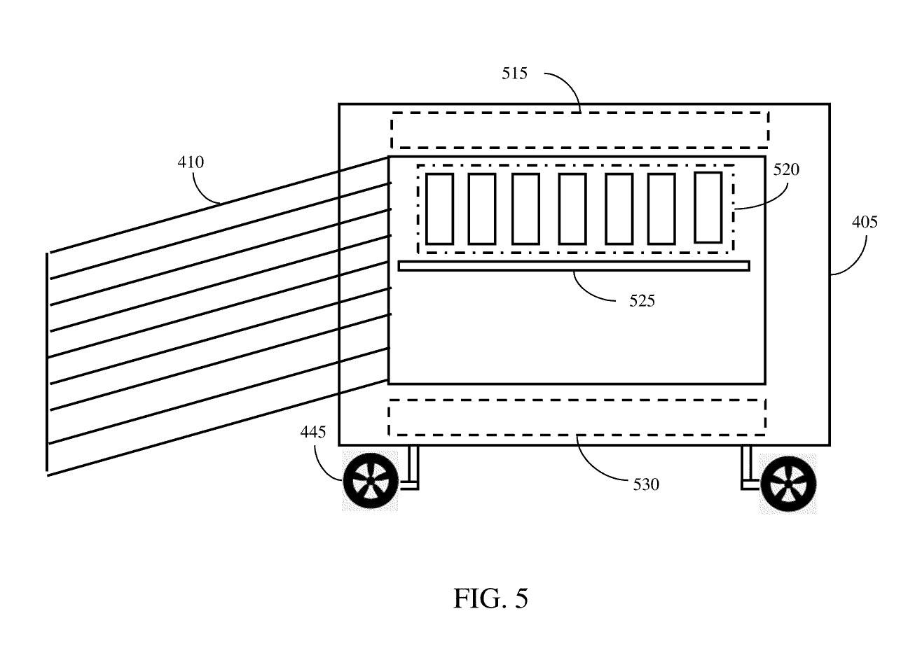

FIG. 5 is a partial cross-sectional view of the mechanical closet to provide a self-contained wireless network environment that serves content and application, manages, and controls multiple tablet devices, in accordance with one embodiment.

The mechanical closet 405 includes the door 410 as described in FIG. 4. Additional, the mechanical closet 405 includes an embedded server 515, individual slots 520, a shelf 525 and an embedded uninterrupted power supply unit 530. Typically, the server 515 is a Linux based computer. In some embodiments, the server 515 can be configured by administrators to port their applications which are subsequently accessed by the users of the tablets. The individual slots 520 are arranged in multiple columns on the shelf 525. The mechanical closet 405 can be configured with any number of slots. Alike the columns, multiple rows exists within the mechanical closet 405 to hold the individual slots 520.

The embedded uninterrupted power supply unit 530 ensures continuous charging of the tablets. In some embodiments, a battery can be placed within the cart to avoid system shutdown in scenarios of accidental un-plugging.

Advantageously, the proposed system provides an environment that permits an organization to provide a secured, wireless LAN to users (for example, students in a classroom or patrons in a restaurant). The cart offers an excellent storage space for a large number of tablet devices. Further, multiple tablet devices stored in the cart can be charged simultaneously with a single power supply. The single power supply acts as a replacement for multiple power supplies. Consequently, hardware requirements for charging are minimized and the entire process of charging happens to be simple and time efficient.

It is to be understood that although various components are illustrated herein as separate entities, each illustrated component represents a collection of functionalities which can be implemented as software, hardware, firmware or any combination of these. Where a component is implemented as software, it can be implemented as a standalone program, but can also be implemented in other ways, for example as part of a larger program, as a plurality of separate programs, as a kernel loadable module, as one or more device drivers or as one or more statically or dynamically linked libraries.

As will be understood by those familiar with the art, the invention may be embodied in other specific forms without departing from the spirit or essential characteristics thereof. Likewise, the particular naming and division of the portions, modules, agents, managers, components, functions, procedures, actions, layers, features, attributes, methodologies and other aspects are not mandatory or significant, and the mechanisms that implement the invention or its features may have different names, divisions and/or formats.

Furthermore, as will be apparent to one of ordinary skill in the relevant art, the portions, modules, agents, managers, components, functions, procedures, actions, layers, features, attributes, methodologies and other aspects of the invention can be implemented as software, hardware, firmware or any combination of the three. Of course, wherever a component of the present invention is implemented as software, the component can be implemented as a script, as a standalone program, as part of a larger program, as a plurality of separate scripts and/or programs, as a statically or dynamically linked library, as a kernel loadable module, as a device driver, and/or in every and any other way known now or in the future to those of skill in the art of computer programming. Additionally, the present invention is in no way limited to implementation in any specific programming language, or for any specific operating system or environment.

Furthermore, it will be readily apparent to those of ordinary skill in the relevant art that where the present invention is implemented in whole or in part in software, the software components thereof can be stored on computer readable media as computer program products. Any form of computer readable medium can be used in this context, such as magnetic or optical storage media. Additionally, software portions of the present invention can be instantiated (for example as object code or executable images) within the memory of any programmable computing device.

Accordingly, the disclosure of the present invention is intended to be illustrative, but not limiting, of the scope of the invention, which is set forth in the following claims.

What is claimed is:

1. A mechanical closet for providing a self-contained wireless network environment that serves content and application, manages, and controls multiple tablet devices, the mechanical closet comprising:
a plurality of slots arranged in multiple rows and columns, each of the slots adapted to hold a tablet device;
an Alternating Current power supply for charging multiple tablet devices simultaneously; and
a Wi-Fi router to provide Local Area Network for content delivery in a class-room and to provide internet connectivity to the multiple tablet devices.

2. The mechanical closet as claimed in claim 1, wherein the mechanical closet has a door, the door comprises a handle with a lock.

3. The mechanical closet as claimed in claim 1, wherein the mechanical closet comprises a plurality of rubber wheels with brakes to enable effortless movement of the mechanical closet over hard flooring.

4. The mechanical closet as claimed in claim 1, wherein the mechanical closet comprises a recoiled power chord.

5. The mechanical closet as claimed in claim 1, wherein the mechanical closet comprises a handle grip to hold and drag.

6. The mechanical closet as claimed in claim 1, wherein the mechanical closet comprises of a plurality of Universal Serial Bus outlets.

7. The mechanical closet as claimed in claim 1, wherein the wireless Local Area Network comprises a switch and a router to enable connectedness in a classroom.

8. The mechanical closet as claimed in claim 1, further comprising:
a server to enable a plurality of activities to users of the multiple tablet devices; and
a managing application residing on each of the tablet devices that communicates with the web server.

9. A computer-implemented method for providing a self-contained wireless network environment that serves content and application, manages, and controls multiple tablet devices, the computer-implemented method comprising:
registering multiple electronic devices with a server application placed within a server embedded in a cart, the electronic devices are tablet devices; and
managing the registered electronic devices.

10. The computer-implemented method as claimed in claim 9, wherein managing further comprises:
tracking state of health of battery of the electronic devices and charge of individual electronic devices.

11. The computer-implemented method as claimed in claim 9 wherein the cart maintains the electronic devices within an optimal temperature through adequate ventilation.

12. A computer program product stored on a non-transitory computer-readable medium that when executed by a processor, performs a method for providing a self-contained wireless network environment that serves content and application, manages, and controls multiple tablet devices, comprising:
registering multiple electronic devices with a server application placed within a server embedded in a cart, the electronic devices are tablet devices; and
managing the registered electronic devices.

13. The computer program product as claimed in claim 12, wherein managing further comprises:
tracking state of health of battery of the electronic devices and charge of individual electronic devices.

14. The computer program product as claimed in claim 12 wherein the cart maintains the electronic devices within an optimal temperature.
